(19) United States
(12) Patent Application Publication
(10) Pub. No.: US 2018/0186163 A1
(43) Pub. Date: Jul. 5, 2018

(54) ELECTRONIC CARD WITH SECURED SWITCH CONNECTION

(71) Applicant: Shenzhen Winpsheng Craft Company Limited, Shenzhen (CN)

(72) Inventor: Jingyun Sun, Shenzhen (CN)

(21) Appl. No.: 15/802,514

(22) Filed: Nov. 3, 2017

(30) Foreign Application Priority Data
Dec. 30, 2016 (CN) 201621494312.3

(51) Int. Cl. B42D 15/02; B42D 15/04; H05K 7/14; B42D 15/00

(52) U.S. Cl. CPC B42D 15/022; B42D 15/027; B42D 15/045; G09F 1/04; H05K 7/1405; B42D 15/0093; B42D 15/042

(57) ABSTRACT

An electronic card with secured switch connection includes a circuit board and an insulation sheet; a contact plate and a elastic sheet provided on the circuit board and acting as a switch, the elastic sheet resiliently pressed against the contact plate, the insulation sheet being slidable between the contact plate and the elastic sheet; a U-shaped snap-engaging sleeve provided on the circuit board and located above the contact plate and the elastic sheet, the insulation sheet being slidably inserted in the U-shaped snap-engaging sleeve, one end of the insulation sheet being provided with a through hole, the circuit board and a fixed end of the insulation sheet being fixed on two sides of a folding electronic card respectively. The electronic card with secured switch connection is advantageous in that it can prevent displacement of the insulation sheet.

### CROSS REFERENCE TO RELATED APPLICATIONS

The present application claims the benefit of Chinese Patent Application No. 201621494312.3 filed on Dec. 30, 2016. All the above are hereby incorporated by reference.

### FIELD OF THE TECHNOLOGY

The present disclosure relates to an electronic product, and more particularly to an electronic card with secured switch connection which can prevent displacement of the insulation sheet in the card.

### BACKGROUND

An electronic card is mainly used as a celebration gift in festival such as birthday. When the card is opened, sweet blessing music will be played. The switch mechanism of a traditional electronic card mainly relies on pulling or sliding of a PVC film out of metal elastic sheet to trigger a circuit. The structure is simple. However, there is a potential problem. When the opening angle of the card is too wide, the PVC film may pop up to the surface of the metal elastic sheet, and can no longer be moved along a normal track, resulting in a defective product.

### SUMMARY

In order to overcome the drawbacks of the prior art, it is an object of the present application to provide an electronic card with secured switch connection which can prevent displacement of the insulation sheet in the card.

The electronic card with secured switch connection is achieved by the following technical measures. An electronic card with secured switch connection, including a circuit board and an insulation sheet; a contact plate and a elastic sheet provided on the circuit board and acting as a switch, the elastic sheet resiliently being pressed against the contact plate, the insulation sheet being slidable between the contact plate and the elastic sheet; a U-shaped snap-engaging sleeve provided on the circuit board and located above the contact plate and the elastic sheet, the insulation sheet being slidably inserted in the U-shaped snap-engaging sleeve, one end of the insulation sheet being provided with a through hole, the circuit board and a fixed end of the insulation sheet being fixed on two sides of a folding card respectively; and when the card is unfolded, a movable end of the insulation sheet slides so that the contact plate and the elastic sheet are in contact at the through hole, and when the card is folded, the movable end of the insulation sheet slides between the contact plate and the elastic sheet so that the contact plate and the elastic sheet are insulated from each other by the insulation sheet.

In a preferred embodiment, the circuit board is provided with two engaging openings on two opposite sides of the contact plate respectively, and the U-shaped snap-engaging sleeve is snap-engaged on the circuit board through the engaging openings.

In a preferred embodiment, the insulation sheet is a PVC film.

In a preferred embodiment, the circuit board is further provided with a button battery and a speaker.

In a preferred embodiment, a hollow is provided at a position of the U-shaped snap-engaging sleeve corresponding to the contact plate.

The insulation sheet of the present disclosure is inserted in the U-shaped snap-engaging sleeve. When the insulation sheet is in the pulling or sliding process, it cannot be popped out from the metal elastic sheet due to the function of the U-shaped snap-engaging sleeve. The insulation sheet must move along the direction of the confined space defined by the U-shaped snap-engaging sleeve. This ensures that the insulation sheet cannot fall out during the sliding process, and can only slide along a fixed direction. The structure is simple and practical. It can reduce the defect rate in actual production. The production process is simple, and the production cost can be reduced while reducing the defect rate.

### BRIEF DESCRIPTION OF THE DRAWINGS

FIG. 1 is an exploded schematic view of an embodiment of the electronic card with secured switch connection.

FIG. 2 is a schematic view of an embodiment of the electronic card with secured switch connection.

### DETAILED DESCRIPTION

The electronic card with secured switch connection of the present application will now be described in further detail with reference to the accompanying drawings.

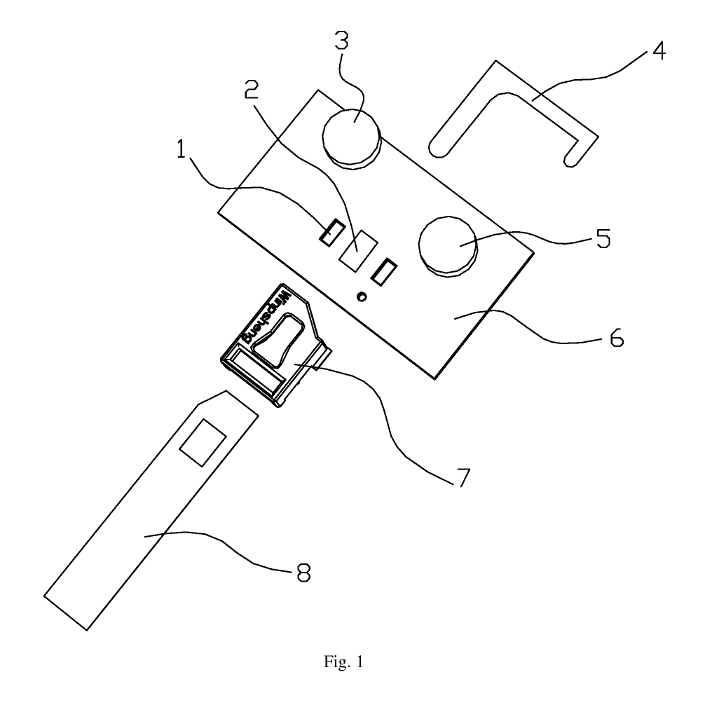

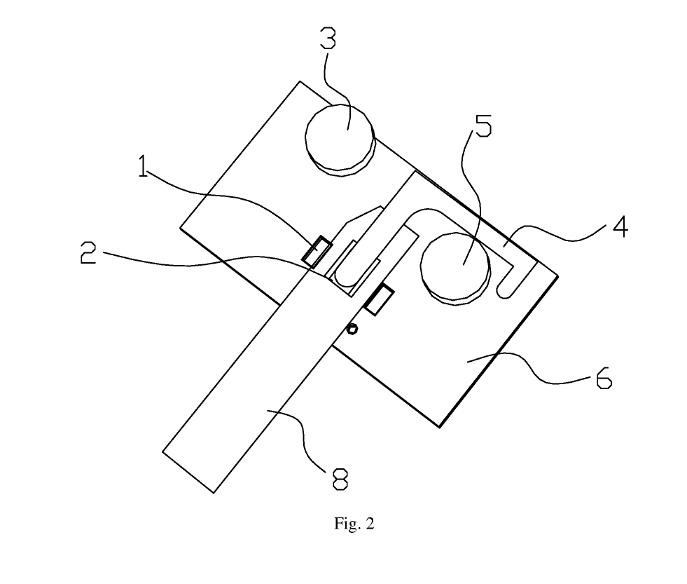

An electronic card with secured switch connection, as shown in FIGS. 1 and 2, may include a circuit board 6 and an insulation sheet 8. A contact plate 2 and an elastic sheet 4, together acting as a switch, may be provided on the circuit board 6. The elastic sheet 4 can be resiliently pressed against the contact plate 2. The insulation sheet 8 can be slidable between the contact plate 2 and the elastic sheet 4. A U-shaped snap-engaging sleeve 7 may be provided on the circuit board 6 and may be located above the contact plate 2 and the elastic sheet 4. The insulation sheet 8 can be slidably inserted in the U-shaped snap-engaging sleeve 7. One end of the insulation sheet 8 may be provided with a through hole. The circuit board 6 and a fixed end of the insulation sheet 8 may be fixed on two sides of a folding electronic card respectively. When the card is unfolded, a movable end of the insulation sheet 8 slides so that the contact plate 2 and the elastic sheet 4 are in contact with each other at the through hole. When the card is folded, the movable end of the insulation sheet 8 slides between the contact plate 2 and the elastic sheet 4 so that the contact plate 2 and the elastic sheet 4 are insulated from each other by the insulation sheet 8.

The insulation sheet 8 of the present disclosure can be inserted in the U-shaped snap-engaging sleeve 7. When the insulation sheet 8 is in the pulling or sliding process, it cannot be popped out from the metal elastic sheet 4 due to the function of the U-shaped snap-engaging sleeve 7. The insulation sheet 8 must move along the direction of the confined space defined by the U-shaped snap-engaging sleeve 7. This can ensure that the insulation sheet 8 cannot fall out during the sliding process, and can only slide along a fixed direction. The structure is simple and practical. It can reduce the defect rate in actual production. The production process is simple, and the production cost can be reduced while reducing the defect rate.

In the embodiment of the electronic card with secured switch connection, shown in FIGS. 1 and 2 and based on the above-mentioned technical scheme, the circuit board 6 may be provided with two snap-engaging openings 1 on two opposite sides of the contact plate 2 respectively. The U-shaped snap-engaging sleeve 7 can be snap-engaged on the circuit board 6 through the snap-engaging openings 1. This can facilitate production and processing.

In the embodiment of the electronic card with secured switch connection, shown in FIGS. 1 and 2 and based on the above-mentioned technical scheme, the insulation sheet 8 can be a PVC film.

In the embodiment of the electronic card with secured switch connection, shown in FIGS. 1 and 2 and based on the above-mentioned technical scheme, the circuit board 6 may be further provided with a button battery 5 and a speaker 3. In other embodiments, the circuit board 6 may be further provided with LED lights.

In the embodiment of the electronic card with secured switch connection, shown in FIGS. 1 and 2 and based on the above-mentioned technical scheme, a hollow may be provided at a position of the U-shaped snap-engaging sleeve 7 corresponding to the contact plate 2. This can facilitate a person to check whether the assembly is in place during processing and using of the product.

The above is a description that assists the understanding of the electronic card with secured switch connection of the present application. The embodying of the electronic card with secured switch connection of the present application is not limited by the above-described embodiments. Any alteration, modification, substitution, combination, and addition that do not depart from the principle of the electronic card with secured switch connection of the present application should be equivalent replacements that are encompassed within the scope of protection of the appended claims.

What is claimed is:

1. An electronic card with secured switch connection, comprising a circuit board and an insulation sheet; a contact plate and an elastic sheet provided on the circuit board and acting as a switch, the elastic sheet resiliently pressed against the contact plate, the insulation sheet being slidable between the contact plate and the elastic sheet; a U-shaped snap-engaging sleeve provided on the circuit board and located above the contact plate and the elastic sheet, the insulation sheet being slidably inserted in the U-shaped snap-engaging sleeve, one end of the insulation sheet being provided with a through hole, the circuit board and a fixed end of the insulation sheet being fixed on two sides of a folding electronic card respectively; and when the card is unfolded, a movable end of the insulation sheet slides so that the contact plate and the elastic sheet are in contact with each other at the through hole, and when the card is folded, the movable end of the insulation sheet slides between the contact plate and the elastic sheet so that the contact plate and the elastic sheet are insulated from each other by the insulation sheet.

2. The electronic card with secured switch connection according to claim 1, wherein the circuit board is provided with two snap-engaging openings on two opposite sides of the contact plate respectively, and the U-shaped snap-engaging sleeve is snap-engaged on the circuit board through the snap-engaging openings.

3. The electronic card with secured switch connection according to claim 1, wherein the insulation sheet is a PVC film.

4. The electronic card with secured switch connection according to claim 1, wherein the circuit board is further provided with a button battery and a speaker.

5. The electronic card with secured switch connection according to claim 4, wherein a hollow is provided at a position of the U-shaped snap-engaging sleeve corresponding to the contact plate.
